(19) United States
(12) Patent Application Publication
(10) Pub. No.: US 2026/0223538 A1
(43) Pub. Date: Jul. 30, 2026

(54) DISPLAY DEVICE

(71) Applicant: SHARP DISPLAY TECHNOLOGY CORPORATION, Kameyama City, Mie (JP)

(72) Inventor: Shogo MURASHIGE, Kameyama City, Mie (JP)

(21) Appl. No.: 19/149,072

(22) PCT Filed: Jan. 18, 2023
(86) PCT No.: PCT/JP2023/001341

§ 371 Date: Jul. 17, 2025

(51) Int. Cl. H10K 59/121

(52) U.S. Cl. CPC H10K 59/1213

(57) ABSTRACT

A first TFT including a first semiconductor layer made of an oxide semiconductor and a second TFT including a second semiconductor layer made of an oxide semiconductor are provided for each subpixel, the first TFT has a top contact structure in which the first TFT is electrically connected to a first terminal electrode and a second terminal electrode on a side opposite to a base substrate of the first semiconductor layer, and the second TFT has a bottom contact structure in which the first TFT is electrically connected to a third terminal electrode and a fourth terminal electrode on the base substrate side of the second semiconductor layer.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. In the organic EL display device, a plurality of thin film transistors (hereinafter also referred to as “TFTs”) are provided for each subpixel, which is the smallest unit of an image. Here, well-known examples of a semiconductor layer constituting the TFT are a semiconductor layer made of polysilicon having high mobility, a semiconductor layer made of an oxide semiconductor such as In—Ga—Zn—O having a low leakage current, and the like.

For example, PTL 1 discloses a display device including a drive transistor in which a first gate electrode having a dual gate structure is provided above a semiconductor layer formed of an oxide semiconductor and a second gate electrode is provided below the semiconductor layer.

### CITATION LIST

### Patent Literature

PTL 1: WO 2021/199112

### SUMMARY

### Technical Problem

Meanwhile, in an organic EL display device in which a plurality of TFTs each using an oxide semiconductor are provided in each subpixel, for example, in a drive TFT for controlling a current value flowing through an organic EL element, since it is necessary to finely control luminance of the organic EL element depending on the current value, a current value change with respect to a gate voltage change in Vg (gate voltage)−Id (drain current) characteristics is required to be small, that is, a subthreshold coefficient (S value) is required to be large. Further, a selection TFT other than the drive TFT needs high-speed switching, and thus, the S value is required to be small. As described above, in a display device in which the plurality of TFTs each using the oxide semiconductor are provided in each subpixel, required characteristics vary depending on a function of each TFT as a transistor, and it is difficult to provide characteristics suitable for each function with one structure, and thus, there is room for improvement.

The disclosure has been made in view of this, and an object of the disclosure is to optimize the characteristics of each TFT in the display device in which the plurality of TFTs each using the oxide semiconductor are provided in the subpixel.

### Solution to Problem

In order to achieve the above object, a display device according to the disclosure includes a base substrate and a thin film transistor layer provided on the base substrate, in which in the thin film transistor layer, a first thin film transistor including a first semiconductor layer made of an oxide semiconductor and a second thin film transistor including a second semiconductor layer made of an oxide semiconductor are provided for each of subpixels constituting a display region, the first thin film transistor includes the first semiconductor layer in which a first conductor region and a second conductor region are defined to be separated from each other and a first channel region is defined between the first conductor region and the second conductor region, a first gate electrode provided overlapping the first channel region on the first semiconductor layer via a first inorganic insulating film, and a first terminal electrode and a second terminal electrode provided to be separated from each other on a side opposite to the base substrate than the first gate electrode and electrically connected to the first conductor region and the second conductor region, respectively, and the second thin film transistor includes the second semiconductor layer in which a third conductor region and a fourth conductor region are defined to be separated from each other and a second channel region is defined between the third conductor region and the fourth conductor region, a first relay electrode and a second relay electrode provided on a base substrate side of the second semiconductor layer and arranged in contact with the third conductor region and the fourth conductor region, respectively, a second gate electrode provided on the second semiconductor layer to overlap the second channel region via a second inorganic insulating film, and a third terminal electrode and a fourth terminal electrode provided to be separated from each other on a side opposite to the base substrate with respect to the second gate electrode and electrically connected to the first relay electrode and the second relay electrode, respectively.

### Advantageous Effects of Disclosure

According to the aspect of the disclosure, in a display device in which a plurality of TFTs each using an oxide semiconductor are provided in a subpixel, characteristics of each TFT can be optimized.

### BRIEF DESCRIPTION OF DRAWINGS

FIG. 1 is a block diagram of an overall configuration of an organic EL display device according to a first embodiment of the disclosure.

FIG. 2 is an equivalent circuit diagram of a pixel circuit of a TFT layer constituting the organic EL display device according to the first embodiment of the disclosure.

FIG. 3 is a plan view illustrating a schematic configuration of the TFT layer constituting the organic EL display device according to the first embodiment of the disclosure.

FIG. 4 is a cross-sectional view of the organic EL display device according to the first embodiment of the disclosure.

FIG. 5 is a cross-sectional view of an organic EL layer constituting the organic EL display device according to the first embodiment of the disclosure.

FIG. 6 is a timing chart for describing an operation of the pixel circuit of the organic EL display device according to the first embodiment of the disclosure.

FIG. 7 is a cross-sectional view illustrating a part of a forming step of the TFT layer constituting the organic EL display device according to the first embodiment of the disclosure.

FIG. 8 is a cross-sectional view illustrating a part of a forming step of the TFT layer subsequent to FIG. 7.

FIG. 9 is a cross-sectional view of an organic EL display device according to a second embodiment of the disclosure.

FIG. 10 is a cross-sectional view illustrating a part of a forming step of the TFT layer constituting the organic EL display device according to the second embodiment of the disclosure.

FIG. 11 is a cross-sectional view illustrating a part of a forming step of the TFT layer subsequent to FIG. 10.

FIG. 12 is a cross-sectional view illustrating a part of a forming step of the TFT layer subsequent to FIG. 11.

FIG. 13 is a cross-sectional view of an organic EL display device according to a third embodiment of the disclosure.

FIG. 14 is a cross-sectional view illustrating a part of a forming step of the TFT layer constituting the organic EL display device according to the third embodiment of the disclosure.

FIG. 15 is a cross-sectional view illustrating a part of a forming step of the TFT layer subsequent to FIG. 14.

FIG. 16 is a cross-sectional view illustrating a part of a forming step of the TFT layer subsequent to FIG. 15.

FIG. 17 is a cross-sectional view illustrating a part of a forming step of the TFT layer subsequent to FIG. 16.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

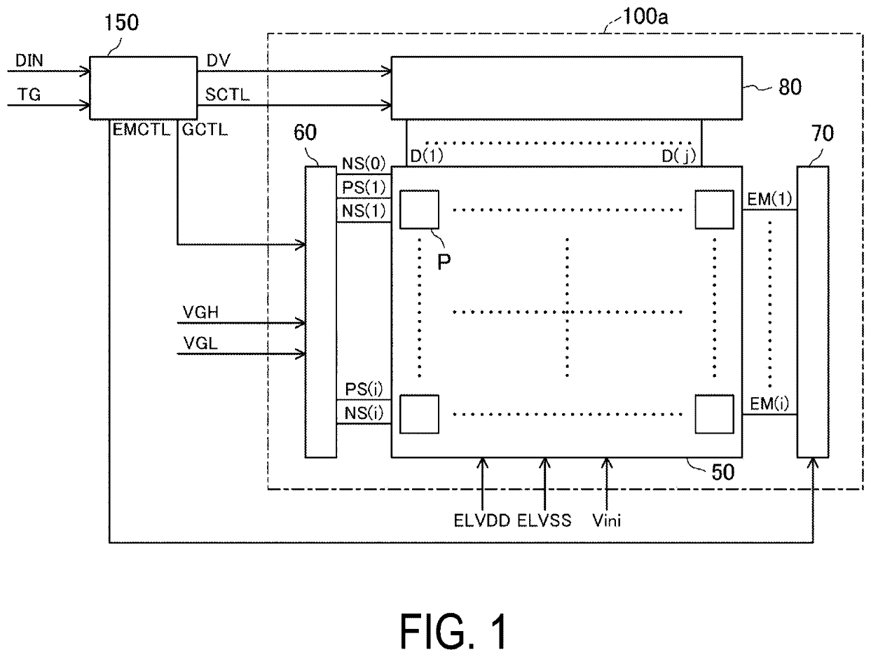

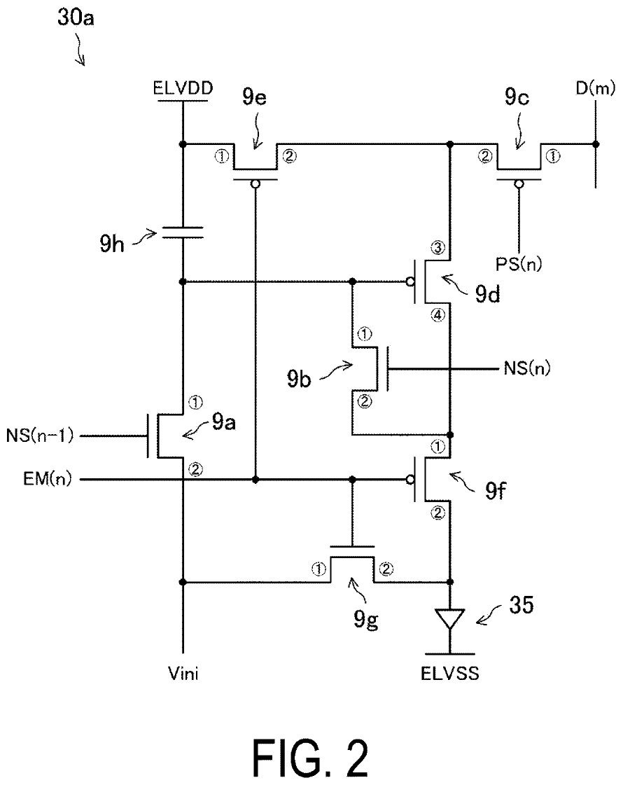

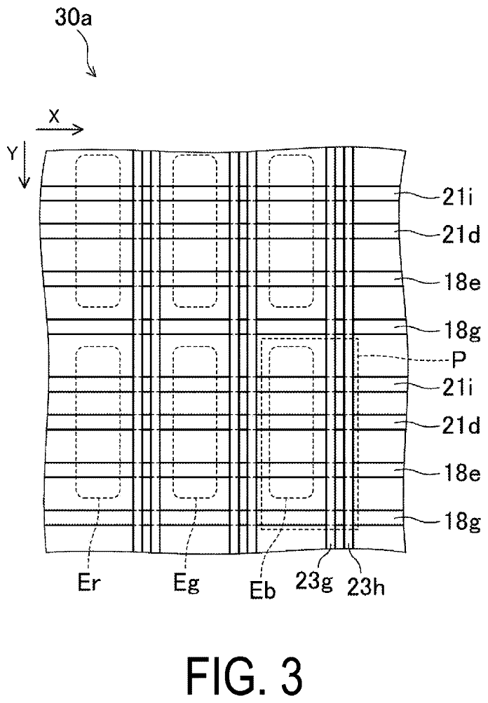

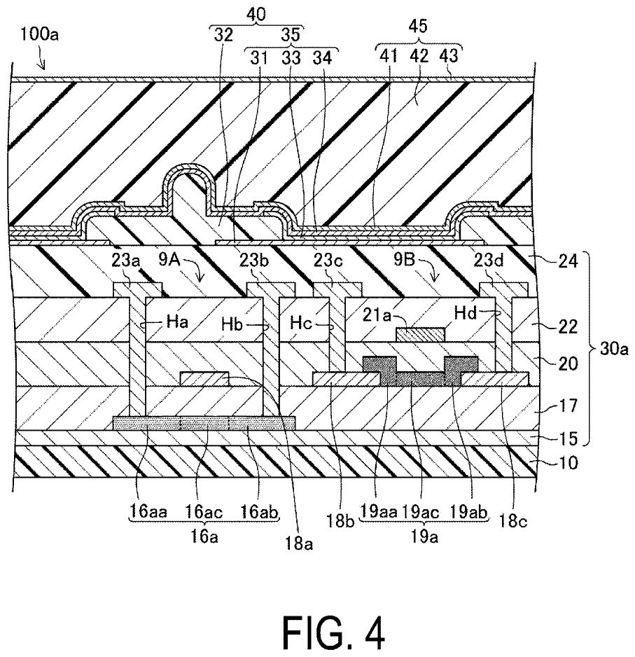

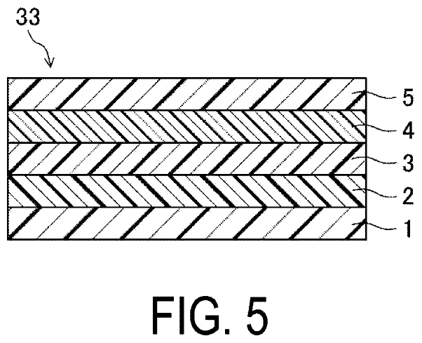

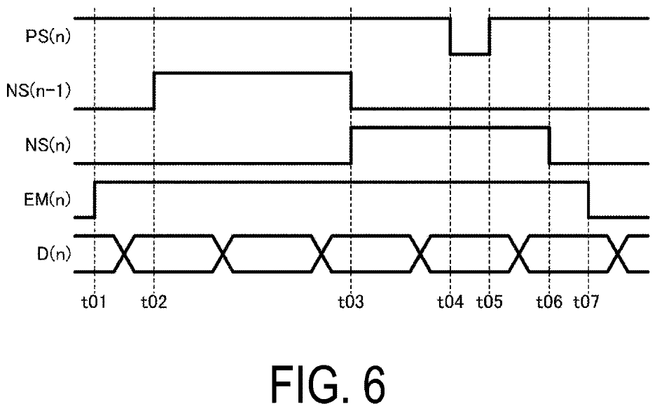

FIGS. 1 to 8 illustrate a first embodiment of a display device according to the disclosure. Note that, in each of the following embodiments, an organic EL display device including an organic EL element layer is exemplified as a display device including a light-emitting element layer. Here, FIG. 1 is a block diagram of an overall configuration of an organic EL display device 100a according to the present embodiment. FIG. 2 is an equivalent circuit diagram of a pixel circuit of a TFT layer 30a constituting the organic EL display device 100a. FIG. 3 is a plan view illustrating a schematic configuration of the TFT layer 30a. Further, FIG. 4 is a cross-sectional view of the organic EL display device 100a. FIG. 5 is a cross-sectional view of an organic EL layer 33 constituting the organic EL display device 100a. FIG. 6 is a timing chart for describing an operation of the pixel circuit of the organic EL display device 100a.

As illustrated in FIG. 1, the organic EL display device 100a is provided with a display region 50 in which a plurality of subpixels P are provided in a matrix shape, and a gate driver 60, an emission driver 70, and a source driver 80 provided in a frame region around the display region 50. Note that as illustrated in FIG. 1, a display control circuit 150 that is electrically connected to the gate driver 60, the emission driver 70, and the source driver 80 is provided outside the organic EL display device 100a.

As illustrated in FIG. 4, the organic EL display device 100a includes a resin substrate 10 provided as a base substrate, the TFT layer 30a provided on the resin substrate 10, an organic EL element layer 40 provided as a light-emitting element layer on the TFT layer 30a, and a sealing film 45 provided on the organic EL element layer 40.

The resin substrate 10 is formed of, for example, a polyimide resin or the like.

As illustrated in FIG. 4, the TFT layer 30a includes a base coat film 15 provided on the resin substrate 10, six first TFTs 9A, one second TFT 9B, and one capacitor 9h (see FIG. 2) provided on the base coat film 15 for each subpixel P, and a flattening film 24 provided on each first TFT 9A, each second TFT 9B, and each capacitor 9h.

As illustrated in FIG. 1, i pieces of first scanning signal lines PS(1) to PS(i), (i+1) pieces of second scanning signal lines NS(0) to NS(i), i pieces of light emission control lines EM(1) to EM(i), and j pieces of data signal lines D(1) to D(j) are provided in the display region 50 of the TFT layer 30a. Note that each of i and j is an integer equal to or greater than 2, n is an integer in a range from 1 to i, and m is an integer in a range from 1 to j. Further, in FIG. 1, the first scanning signal lines PS, the second scanning signal lines NS, and the data signal lines D are not illustrated in the display region 50. Here, the first scanning signal lines PS(1) to PS(i) are signal lines for transmitting first scanning signals, which are control signals for the P-channel type transistors. Further, the second scanning signal lines NS(0) to NS(i) are signal lines for transmitting second scanning signals, which are control signals for the N-channel type transistors. Further, the light emission control lines EM(1) to EM(i) are signal lines for transmitting light emission control signals. Note that the first scanning signal lines PS(1) to PS(i), the second scanning signal lines NS(0) to NS(i), and the light emission control lines EM(1) to EM(i) are provided in parallel with each other. Further, the first scanning signal lines PS(1) to PS(i) and the data signal lines D(1) to D(j) are provided to be orthogonal to each other. Further, in a timing chart in FIG. 6, the reference signs PS(1) to PS(i) are also assigned to the first scanning signals supplied to each of the first scanning signal lines PS(1) to PS(i), the reference signs NS(0) to NS(i) are also assigned to the second scanning signals supplied to each of the second scanning signal lines NS(0) to NS(i), the reference signs EM(1) to EM(i) are also assigned to the light emission control signals supplied to each of the light emission control lines EM(1) to EM(i), and the reference signs D(1) to D(j) are also assigned to data signals (data voltages) supplied to each of the data signal lines D(1) to D(j).

Furthermore, a power supply line that supplies a high-level power supply voltage ELVDD (hereinafter, referred to as a “high-level power supply line”) for driving an organic EL element 35 to be described later, a power supply line that supplies a low-level power supply voltage ELVSS (hereinafter, referred to as a “low-level power supply line”) for driving the organic EL element 35, and a power supply line that supplies an initialization voltage Vini (hereinafter, referred to as an “initialization power supply line”) are provided in the display region 50 of the TFT layer 30a. Note that, in the present embodiment, as necessary, the reference sign ELVDD is also assigned to the high-level power supply line, the reference sign ELVSS is also assigned to the low-level power supply line, and the reference sign Vini is also assigned to the initialization power supply line. The high-level power supply voltage ELVDD, the low-level power supply voltage ELVSS, and the initialization voltage Vini are supplied from power source circuits that are not illustrated. In a plan view of FIG. 3, a first scanning signal line 18g extending in the X direction is illustrated as the first scanning signal line PS, a light emission control line 18e extending in the X direction is illustrated as the light emission control line EM, a second scanning signal line 21d extending in the X direction is illustrated as the second scanning signal line NS, an initialization power supply line 21i extending in the X direction is illustrated as the initialization power supply line Vini, a data signal line 23g extending in the Y direction is illustrated as the data signal line D, and a high-level power supply line 23h extending in the Y direction is illustrated as a high-level power supply line ELVDD.

The base coat film 15, a first gate insulating film 17 provided as a first inorganic insulating film, a second gate insulating film 20 provided as a second inorganic insulating film, and an interlayer insulating film 22 provided as a third inorganic insulating film are each formed of, for example, a single-layer film of an inorganic insulating film such as silicon nitride, silicon oxide, or silicon oxynitride, or a layered film thereof. Here, at least a portion of the base coat film 15 on a first semiconductor layer 16a side described below, a portion of the first gate insulating film 17 on the first semiconductor layer 16a side and a second semiconductor layer 19a side described below, and a portion of the second gate insulating film 20 on the second semiconductor layer 19a side are each formed of, for example, a silicon oxide film.

As illustrated in FIG. 4, the first TFT 9A includes the first semiconductor layer 16a provided on the base coat film 15, a first gate electrode 18a provided on the first semiconductor layer 16a with the first gate insulating film 17 interposed therebetween, and a first terminal electrode 23a and a second terminal electrode 23b provided separated from each other on the interlayer insulating film 22. Here, as illustrated in FIG. 4, since the first TFT 9A has a top contact structure, the first TFT 9A is provided so that the S value becomes small.

The first semiconductor layer 16a is made of, for example, an In—Ga—Zn—O-based oxide semiconductor, and includes, as illustrated in FIG. 4, a first conductor region 16aa and a second conductor region 16ab defined to be separated from each other, and a first channel region 16ac defined between the first conductor region 16aa and the second conductor region 16ab. Here, the In—Ga—Zn—O-based semiconductor is a ternary oxide of indium (In), gallium (Ga), and zinc (Zn), and a ratio (a composition ratio) of each of In, Ga, and Zn is not particularly limited to a specific value. The In—Ga—Zn—O-based semiconductor may be an amorphous semiconductor or may be a crystalline semiconductor. Note that as a crystalline In—Ga—Zn—O-based semiconductor, a crystalline In—Ga—Zn—O-based semiconductor in which the c-axis is oriented substantially perpendicular to the layer surface is preferable. In place of the In—Ga—Zn—O-based semiconductor, another oxide semiconductor may be included. Examples of the other oxide semiconductor may include an In—Sn—Zn—O-based semiconductor (for example, In₂O₃—SnO₂—ZnO; InSnZnO). Here, the In—Sn—Zn—O-based semiconductor is a ternary oxide of indium (In), tin (Sn), and zinc (Zn). Alternatively, examples of the other oxide semiconductor may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, cadmium oxide (CdO), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, an In—Ga—Zn—Sn—O-based semiconductor, InGaO₃(ZnO)₅, magnesium zinc oxide (MgₓZn₁₋ₓO), and cadmium zinc oxide (CdₓZn₁₋ₓO). Note that, as the Zn—O-based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a semiconductor in a polycrystalline state, a semiconductor in a microcrystalline state in which the non-crystalline state and the polycrystalline state are mixed, or a semiconductor to which no impurity element is added can be used.

As illustrated in FIG. 4, the first gate electrode 18a is provided to overlap the first channel region 16ac of the first semiconductor layer 16a, and is configured to control conduction between the first conductor region 16aa and the second conductor region 16ab of the first semiconductor layer 16a.

As illustrated in FIG. 4, the first terminal electrode 23a and the second terminal electrode 23b are electrically connected to the first conductor region 16aa and the second conductor region 16ab of the first semiconductor layer 16a through a first contact hole Ha and a second contact hole Hb, respectively, formed in the layered film of the first gate insulating film 17, the second gate insulating film 20, and the interlayer insulating film 22.

As illustrated in FIG. 4, the second TFT 9B includes the second semiconductor layer 19a provided on the first gate insulating film 17, a first relay electrode 18b and a second relay electrode 18c provided separated from each other on the resin substrate 10 side of the second semiconductor layer 19a, the second gate electrode 21a provided on the second semiconductor layer 19a with the second gate insulating film 20 interposed therebetween, and a third terminal electrode 23c and a fourth terminal electrode 23d provided separated from each other on the interlayer insulating film 22. Here, as illustrated in FIG. 4, since the second TFT 9B has a bottom contact structure, for example, in order to form the first relay electrode 18b and the second relay electrode 18c, the oxide semiconductor is oxidated due to oxygen ashing at the time of patterning the first metal film by dry etching and a trace amount of residues of a first metal film described later, and thus, the second TFT 9B is provided so that the S value becomes large.

Similar to the first semiconductor layer 16a, the second semiconductor layer 19a is made of, for example, an In—Ga—Zn—O-based oxide semiconductor, and includes, as illustrated in FIG. 4, a third conductor region 19aa and a fourth conductor region 19ab located so as to be separated from each other, and a second channel region 19ac located between the third conductor region 19aa and the fourth conductor region 19ab.

As illustrated in FIG. 4, the first relay electrode 18b and the second relay electrode 18c are provided on the first gate insulating film 17 and are provided so as to be in contact with lower faces of the third conductor region 19aa and the fourth conductor region 19ab of the second semiconductor layer 19a, respectively.

As illustrated in FIG. 4, the second gate electrode 21a is provided so as to overlap the second channel region 19ac of the second semiconductor layer 19a, and is configured to control conduction between the third conductor region 19aa and the fourth conductor region 19ab of the second semiconductor layer 19a.

As illustrated in FIG. 4, the third terminal electrode 23c and the fourth terminal electrode 23d are electrically connected to the first relay electrode 18b and the second relay electrode 18c through a third contact hole Hc and a fourth contact hole Hd, respectively, formed in the layered film of the second gate insulating film 20 and the interlayer insulating film 22.

Note that as illustrated in FIG. 4, in the TFT layer 30a, the base coat film 15, a first semiconductor film serving as the first semiconductor layer 16a or the like, the first gate insulating film 17, a first metal film serving as the first relay electrode 18b or the like, a second semiconductor film serving as the second semiconductor layer 19a or the like, the second gate insulating film 20, a second metal film serving as the second gate electrode 21a or the like, the interlayer insulating film 22, a third metal film serving as the first terminal electrode 23a or the like, and the flattening film 24 are sequentially layered.

In the present embodiment, an initialization TFT 9a, a threshold voltage compensation TFT 9b, a write control TFT 9c, a power supply control TFT 9e, a light emission control TFT 9f, and an anode discharge TFT 9g, which will be described later, are provided as the first TFT 9A, and a drive TFT 9d, which will be described later, is provided as the second TFT 9B (see FIG. 2). Note that in the equivalent circuit diagram in FIG. 2, the first terminal electrode 23a and the second terminal electrode 23b of each of the initialization TFT 9a, the threshold voltage compensation TFT 9b, the write control TFT 9c, the power supply control TFT 9e, the light emission control TFT 9f, and the anode discharge TFT 9g are indicated by circled numbers 1 and 2, respectively, and the third terminal electrode 23c and the fourth terminal electrode 23d of the drive TFT 9d are indicated by circled numbers 3 and 4, respectively.

As illustrated in FIG. 2, the initialization TFT 9a includes the first gate electrode 18a electrically connected to the second scanning signal line NS(n−1) in an (n−1)-th row, the first terminal electrode 23a electrically connected to the first terminal electrode 23a of the threshold voltage compensation TFT 9b, the second gate electrode 21a of the drive TFT 9d, and the capacitor 9h, and the second terminal electrode 23b electrically connected to the initialization power supply line Vini.

As illustrated in FIG. 2, the threshold voltage compensation TFT 9b includes the first gate electrode 18a electrically connected to the second scanning signal line NS(n) in an n-th row, the first terminal electrode 23a electrically connected to the first terminal electrode 23a of the initialization TFT 9a, the second gate electrode 21a of the drive TFT 9d, and the capacitor 9h, and the second terminal electrode 23b electrically connected to the fourth terminal electrode 23d of the drive TFT 9d and the first terminal electrode 23a of the light emission control TFT 9f.

As illustrated in FIG. 2, the write control TFT 9c includes the first gate electrode 18a electrically connected to the first scanning signal line PS(n) in an n-th row, the first terminal electrode 23a electrically connected to the data signal line D(m) in an m-th column, and the second terminal electrode 23b electrically connected to the third terminal electrode 23c of the drive TFT 9d and the second terminal electrode 23b of the power supply control TFT 9e.

As illustrated in FIG. 2, the drive TFT 9d includes the second gate electrode 21a electrically connected to the first terminal electrode 23a of the initialization TFT 9a, the first terminal electrode 23a of the threshold voltage compensation TFT 9b, and the capacitor 9h, the third terminal electrode 23c electrically connected to the second terminal electrode 23b of the write control TFT 9c and the second terminal electrode 23b of the power supply control TFT 9e, and the fourth terminal electrode 23d electrically connected to the second terminal electrode 23b of the threshold voltage compensation TFT 9b and the first terminal electrode 23a of the light emission control TFT 9f. Note that the high-level power supply voltage ELVDD is input to the third terminal electrode 23c of the drive TFT 9d during a period in which the organic EL element 35 emits light, and the data signal D(m) is input to the third terminal electrode 23c of the drive TFT 9d during a period in which writing to the capacitor 9h is performed.

As illustrated in FIG. 2, the power supply control TFT 9e includes the first gate electrode 18a electrically connected to the light emission control line EM(n) in an n-th row, the first terminal electrode 23a electrically connected to the high-level power supply line ELVDD and the capacitor 9h, and the second terminal electrode 23b electrically connected to the second terminal electrode 23b of the write control TFT 9c and the third terminal electrode 23c of the drive TFT 9d.

As illustrated in FIG. 2, the light emission control TFT 9f includes the first gate electrode 18a electrically connected to the light emission control line EM(n) in the n-th row, the first terminal electrode 23a electrically connected to the second terminal electrode 23b of the threshold voltage compensation TFT 9b and the fourth terminal electrode 23d of the drive TFT 9d, and the second terminal electrode 23b electrically connected to the second terminal electrode 23b of the anode discharge TFT 9g and a first electrode 31, which will be described later, of the organic EL element 35.

As illustrated in FIG. 2, the anode discharge TFT 9g includes the first gate electrode 18a electrically connected to the light emission control line EM(n) in the n-th row, the first terminal electrode 23a electrically connected to the initialization power supply line Vini, and the second terminal electrode 23b electrically connected to the second terminal electrode 23b of the light emission control TFT 9f and the first electrode 31 of the organic EL element 35.

The capacitor 9h includes, for example, a first capacitance electrode provided in the same layer using the same material as the second gate electrode 21a, a second capacitance electrode provided in the same layer using the same material as the first terminal electrode 23a, and the interlayer insulating film 22 provided between the first capacitance electrode and the second capacitance electrode. Here, the capacitor 9h includes the first capacitance electrode electrically connected to the high-level power supply line ELVDD and the first terminal electrode 23a of the power supply control TFT 9e, and the second capacitance electrode electrically connected to the first terminal electrode 23a of the initialization TFT 9a, the first terminal electrode 23a of the threshold voltage compensation TFT 9b, and the second gate electrode 21a of the drive TFT 9d.

The flattening film 24 has a flat surface in the display region 50, and is made of, for example, an organic resin material such as a polyimide resin or an acrylic resin, or a polysiloxane-based spin on glass (SOG) material.

As illustrated in FIG. 4, the organic EL element layer 40 includes a plurality of the organic EL elements 35 provided as a plurality of light-emitting elements arrayed in a matrix shape in correspondence with the plurality of subpixels P, and an edge cover 32 provided in a lattice pattern shared by all the subpixels P so as to cover peripheral end portions of the first electrode 31 of each of the organic EL elements 35.

As illustrated in FIG. 4, the organic EL element 35 includes, in each of the subpixels P, the first electrode 31 (anode electrode) provided on the flattening film 24 of the TFT layer 30a, an organic EL layer 33 provided on the first electrode 31, and a second electrode 34 (cathode electrode) provided on the organic EL layer 33.

The first electrode 31 is electrically connected to the second terminal electrode 23b of the light emission control TFT 9f of each of the subpixels P, through a contact hole formed in the flattening film 24. Further, the first electrode 31 functions to inject holes (positive holes) into the organic EL layer 33. Further, the first electrode 31 is preferably made of a material having a high work function to improve the efficiency of hole injection into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, examples of the materials constituting the first electrode 31 may include an alloy such as astatine (At)/astatine oxide (AtO2) or the like. Furthermore, examples of the materials constituting the first electrode 31 may include electrically conductive oxide such as tin oxide (SnO), zinc oxide (ZnO), indium tin oxide (ITO), and indium zinc oxide (IZO). Additionally, the first electrode 31 may be formed by layering a plurality of layers made of any of the materials described above. Note that examples of compound materials having a high work function include indium tin oxide (ITO) and indium zinc oxide (IZO).

As illustrated in FIG. 5, the organic EL layer 33 includes a hole injection layer 1, a hole transport layer 2, a light-emitting layer 3, an electron transport layer 4, and an electron injection layer 5, which are sequentially layered on the first electrode 31.

The hole injection layer 1 is also referred to as an anode electrode buffer layer, and functions to reduce an energy level difference between the first electrode 31 and the organic EL layer 33 to thereby improve the efficiency of hole injection into the organic EL layer 33 from the first electrode 31. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 31 to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 31 and the second electrode 34, respectively, and the holes and the electrons recombine in a case where a voltage is applied via the first electrode 31 and the second electrode 34. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33 to thereby improve the efficiency of electron injection into the organic EL layer 33 from the second electrode 34, and this function allows the drive voltage of the organic EL element 35 to be reduced. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 4, the second electrode 34 is provided in common to all of the subpixels P so as to cover each of the organic EL layers 33 and the edge cover 32. Further, the second electrode 34 functions to inject electrons into the organic EL layer 33. Further, the second electrode 34 is preferably formed of a material having a low work function to improve the efficiency of electron injection into the organic EL layer 33. Further, as illustrated in FIG. 2, the second electrode 34 is electrically connected to the low-level power supply line ELVSS. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of an alloy, such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), lithium fluoride (LiF)/calcium (Ca)/aluminum (Al) and the like. Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as a polyimide resin or an acrylic resin, or an SOG material of a polysiloxane based.

As illustrated in FIG. 4, the sealing film 45 is provided covering the second electrode 34, includes a first inorganic sealing film 41, an organic sealing film 42, and a second inorganic sealing film 43 sequentially layered on the second electrode 34, and functions to protect the organic EL layer 33 of the organic EL element 35 from moisture, oxygen, and the like.

The first inorganic sealing film 41 and the second inorganic sealing film 43 are constituted of, for example, an inorganic insulating film such as a silicon nitride film, a silicon oxide film, or a silicon oxynitride film.

The organic sealing film 42 is made of, for example, an organic resin material such as an acrylic resin, an epoxy resin, a silicone resin, a polyurea resin, a parylene resin, a polyimide resin, a polyamide resin, or the like.

Next, an operation of the organic EL display device 100a having the above-described configuration will be described.

### Operation of Peripheral Circuit

As illustrated in FIG. 1, the display control circuit 150 receives an input image signal DIN and a timing signal group (a horizontal synchronization signal, a vertical synchronization signal, and the like) TG transmitted from the outside, and outputs a digital video signal DV, a gate control signal GCTL for controlling the operation of the gate driver 60, an emission driver control signal EMCTL for controlling the operation of the emission driver 70, and a source control signal SCTL for controlling the operation of the source driver 80. Here, the gate control signal GCTL includes a gate start pulse signal, a gate clock signal, and the like. Further, the emission driver control signal EMCTL includes an emission start pulse signal, an emission clock signal, and the like. Further, the source control signal SCTL includes a source start pulse signal, a source clock signal, a latch strobe signal, and the like.

The gate driver 60 is electrically connected to the first scanning signal lines PS(1) to PS(i) and the second scanning signal lines NS(0) to NS(i). Then, based on the gate control signal GCTL output from the display control circuit 150, the gate driver 60 applies the first scanning signal to the first scanning signal lines PS(1) to PS(i), and the second scanning signal to the second scanning signal lines NS(0) to NS(i).

The emission driver 70 is electrically connected to the light emission control lines EM(1) to EM(i). Then, based on the emission driver control signal EMCTL output from the display control circuit 150, the emission driver 70 applies the light emission control signal to the light emission control lines EM(1) to EM(i).

The source driver 80 includes a j-bit shift register, a sampling circuit, a latch circuit, j pieces of D/A converters, and the like, which are not illustrated. Here, the shift register includes j pieces of cascade-connected registers, and based on the source clock signal, the shift register sequentially transfers a pulse of the source start pulse signal supplied to a first stage register from an input end to an output end, and a sampling pulse is output from the register of each stage according to the transfer of the pulse. Then, the sampling circuit stores the digital video signal DV based on the sampling pulse. Then, in accordance with the latch strobe signal, the latch circuit acquires and holds the digital video signal DV for one row stored in the sampling circuit. Then, the D/A converter is provided corresponding to each of the data signal lines D(1) to D(j), converts the digital video signal DV held in the latch circuit to an analog voltage, and applies the converted analog voltage as a data signal (data voltage) to all the data signal lines D(1) to D(j) simultaneously.

As described above, as a result of the data signal being applied to the data signal lines D(1) to D(j), the first scanning signal being applied to the first scanning signal lines PS(1) to PS(i), the second scanning signal being applied to the second scanning signal lines NS(0) to NS(i), and the first light emission control signal being applied to the first light emission control lines EM(1) to EM(i), an image based on the input image signal DIN is displayed in the display region 50.

### Operation of Pixel Circuit

Next, the operation of the pixel circuit of the organic EL display device 100a according to the present embodiment will be described using the timing chart in FIG. 6. Note that the operation of the pixel circuit described here is merely an example, and no limitation thereto is intended.

First, before time t01, the first scanning signal PS(n) is at a high level, and the second scanning signal NS(n−1), the second scanning signal NS(n), and the light emission control signal EM(n) are at a low level. At this time, the power supply control TFT 9e and the light emission control TFT 9f are in an on state, and the anode discharge TFT 9g is in an off state. Accordingly, before time t01, a drive current corresponding to a charging voltage of the capacitor 9h is supplied to the organic EL element 35, and the organic EL element 35 emits light in accordance with the magnitude of the drive current.

At the time t01, as a result of the light emission control signal EM(n) changing from the low level to the high level, the power supply control TFT 9e and the light emission control TFT 9f are in the off state. As a result, the supply of the drive current to the organic EL element 35 is cut off, and the organic EL element 35 is thus in an unlighted state. Further, as a result of the light emission control signal EM(n) changing from the low level to the high level, the anode discharge TFT 9g is in the on state. Thus, the voltage of the first electrode 31 of the organic EL element 35 is initialized based on the initialization voltage Vini.

At a time t02, as a result of the second scanning signal NS(n−1) changing from the low level to the high level, the initialization TFT 9a is in the on state. As a result, a gate voltage of the drive TFT 9d is initialized. In other words, the gate voltage of the drive TFT 9d becomes equal to the initialization voltage Vini.

At a time t03, as a result of the second scanning signal NS(n−1) changing from the high level to the low level, the initialization TFT 9a is in the off state. Further, at the time t03, the second scanning signal NS(n) changes from the low level to the high level. Thus, the threshold voltage compensation TFT 9b is in the on state.

At a time t04, as a result of the first scanning signal PS(n) changing from the high level to the low level, the write control TFT 9c is in the on state. Here, since the threshold voltage compensation TFT 9b is in the on state at the time t03, when the write control TFT 9c enters the on state at the time t04, the data signal D(m) is input to the second capacitance electrode of the capacitor 9h via the write control TFT 9c, the drive TFT 9d, and the threshold voltage compensation TFT 9b. In this way, the capacitor 9h is charged.

At a time t05, as a result of the first scanning signal PS(n) changing from the low level to the high level, the write control TFT 9c is in the off state.

At a time t06, as a result of the second scanning signal NS(n) changing from the high level to the low level, the threshold voltage compensation TFT 9b is in the off state.

At a time t07, as a result of the light emission control signal EM(n) changing from the high level to the low level, the anode discharge TFT 9g is in the off state, and, at the same time, the power supply control TFT 9e and the light emission control TFT 9f are in the on state. In this way, the drive current corresponding to the charging voltage of the capacitor 9h is supplied to the organic EL element 35, and the organic EL element 35 emits light in accordance with the magnitude of the drive current.

Thus, in the organic EL display device 100a, the organic EL element 35 in each subpixel P emits light with luminance corresponding to the drive current, and an image is displayed.

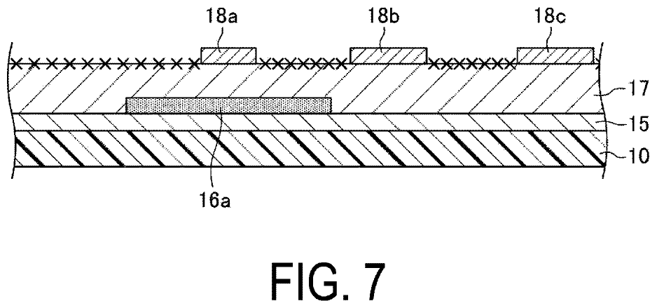

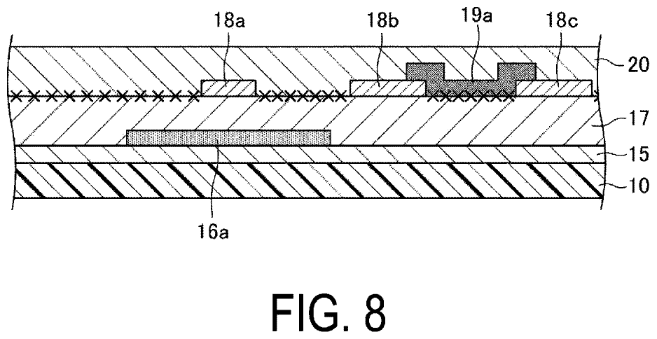

Next, a method for manufacturing the organic EL display device 100a according to the present embodiment will be described. Note that the method for manufacturing the organic EL display device 100a includes a TFT layer forming step, an organic EL element layer forming step, and a sealing film forming step. FIG. 7 is a cross-sectional view illustrating a part of a forming step of the TFT layer 30a. FIG. 8 is a cross-sectional view illustrating a part of a forming step of the TFT layer 30a subsequent to FIG. 7.

### TFT Layer Forming Step

First, for example, a silicon oxide film (having a thickness of about 100 nm) is formed, for example, by plasma chemical vapor deposition (CVD), on the resin substrate 10 formed on a glass substrate, thus forming the base coat film 15.

Subsequently, after forming the first semiconductor film made of an oxide semiconductor by depositing InGaZnO₄ (having a thickness of about 30 nm) or the like by, for example, sputtering on the substrate surface on which the base coat film 15 is formed, the first semiconductor film is patterned to form the first semiconductor layer 16a and the like.

Thereafter, a silicon oxide film (having a thickness of about 100 nm) is formed, for example, by plasma CVD on the substrate surface on which the first semiconductor layer 16a and the like are formed, to form the first gate insulating film 17.

Furthermore, after forming a first metal film by forming a molybdenum film (having a thickness of about 250 nm) or the like by, for example, sputtering on the substrate surface on which the first gate insulating film 17 is formed, the first metal film is patterned to form the first gate electrode 18a, the first relay electrode 18b, the second relay electrode 18c, the first scanning signal line 18g, the light emission control line 18e, and the like as illustrated in FIG. 7. At this time, on the surface of the first gate insulating film 17 exposed from the first gate electrode 18a, the first relay electrode 18b, the second relay electrode 18c, the first scanning signal line 18g, the light emission control line 18e, and the like, as indicated by x marks in FIG. 7, oxygen is adsorbed due to oxygen ashing at the time of dry etching and oxygen adsorbed on residues of the first metal film.

Subsequently, after forming the second semiconductor film made of an oxide semiconductor by depositing InGaZnO₄ (having a thickness of about 30 nm) or the like by, for example, sputtering on the substrate surface on which the first gate electrode 18a and the like are formed, the second semiconductor film is patterned to form the second semiconductor layer 19a and the like. At this time, the second semiconductor layer 19a is oxidized by diffusion of oxygen on the surface of the first gate insulating film 17 (see FIG. 8).

Thereafter, a silicon oxide film (having a thickness of about 100 nm) is formed by, for example, plasma CVD on the substrate surface on which the second semiconductor layer 19a and the like are formed, thereby forming the second gate insulating film 20 as illustrated in FIG. 8.

Furthermore, after forming a second metal film by forming a single-layer film of a molybdenum film (having a thickness of about 250 nm), a layered film in which an aluminum film (having a thickness of about 300 nm) and a titanium film (having a thickness of about 50 nm) are sequentially layered, or a layered film in which a titanium film (having a thickness of about 50 nm), an aluminum film (having a thickness of about 300 nm), and a titanium film (having a thickness of about 50 nm) are sequentially layered by, for example, sputtering on the substrate surface on which the second gate insulating film 20 is formed, the second metal film is patterned to form the second gate electrode 21a, the second scanning signal line 21d, the initialization power supply line 21i and the like.

Subsequently, a silicon oxide film (having a thickness of about 300 nm) and a silicon nitride film (having a thickness of about 150 nm) are sequentially formed by plasma CVD, for example, on the substrate surface on which the second gate electrode 21a and the like are formed to form the interlayer insulating film 22. Note that by performing heat treatment after forming the interlayer insulating film 22, a part of the first semiconductor layer 16a and a part of the second semiconductor layer 19a are made conductive, and the first conductor region 16aa, the second conductor region 16ab, and the first channel region 16ac are formed in the first semiconductor layer 16a, and the third conductor region 19aa, the fourth conductor region 19ab, and the second channel region 19ac are formed in the second semiconductor layer 19a.

Thereafter, on the substrate surface on which the interlayer insulating film 22 is formed, the base coat film 15, the first gate insulating film 17, the second gate insulating film 20, and the interlayer insulating film 22 are appropriately patterned to form the first contact hole Ha, the second contact hole Hb, the third contact hole Hc, and the fourth contact hole Hd.

Furthermore, after forming a third metal film by sequentially forming a titanium film (having a thickness of about 50 nm), an aluminum film (having a thickness of about 400 nm), a titanium film (having a thickness of about 50 nm) and the like by, for example, sputtering, on the substrate surface on which the first contact hole Ha and the like are formed, the third metal film is patterned to form the first terminal electrode 23a, the second terminal electrode 23b, the third terminal electrode 23c, the fourth terminal electrode 23d, the fifth terminal electrode 23e, the sixth terminal electrode 23f, the data signal line 23g, the high-level power supply line 23h, and the like.

Finally, after applying a polyimide-based photosensitive resin film (having a thickness of about 2 μm) to the substrate surface on which the first terminal electrode 23a and the like are formed, by, for example, spin coating or slit coating, pre-baking, exposing, developing, and post-baking are performed on the applied film to form the flattening film 24.

As described above, the TFT layer 30a can be formed.

### Organic EL Element Layer Forming Step

The organic EL element layer 40 is formed by forming, using a known method, the first electrode 31, the edge cover 32, the organic EL layer 33, and the second electrode 34 on the flattening film 24 of the TFT layer 30a that has been formed in the TFT layer forming step.

### Sealing Film Forming Step

First, an inorganic insulating film such as a silicon nitride film, a silicon oxide film, or a silicon oxynitride film is formed by plasma CVD on a substrate surface formed with the organic EL element layer 40 formed in the organic EL element layer forming step described above by using a mask to form the first inorganic sealing film 41.

Next, on the substrate surface on which the first inorganic sealing film 41 is formed, a film made of an organic resin material such as acrylic resin is formed by, for example, using an ink-jet method to form the organic sealing film 42.

Thereafter, an inorganic insulating film such as a silicon nitride film, a silicon oxide film, or a silicon oxynitride film is formed by plasma CVD on the substrate surface formed with the organic sealing film 42 by using a mask to form the second inorganic sealing film 43, thereby forming the sealing film 45.

Finally, after a protective sheet (not illustrated) is applied to the substrate surface formed with the sealing film 45, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off.

The organic EL display device 100a according to the present embodiment can be manufactured as described above.

As described above, according to the organic EL display device 100a of the present embodiment, the initialization TFT 9a, the threshold voltage compensation TFT 9b, the write control TFT 9c, the power supply control TFT 9e, the light emission control TFT 9f, and the anode discharge TFT 9g each provided as the first TFT 9A each have the top contact structure, and the drive TFT 9d provided as the second TFT 9B has the bottom contact structure. Here, in the drive TFT 9d having the bottom contact structure, when the first relay electrode 18b and the second relay electrode 18c are formed, oxygen is adsorbed on the surface of the first gate insulating film 17. Thus, the second semiconductor layer 19a formed thereafter is oxidized. As a result, since the S value becomes large in the drive TFT 9d, the luminance of the organic EL element 35 of each subpixel P can be finely controlled by finely controlling the current value flowing through the organic EL element 35. On the other hand, in the initialization TFT 9a, the threshold voltage compensation TFT 9b, the write control TFT 9c, the power supply control TFT 9e, the light emission control TFT 9f, and the anode discharge TFT 9g each having the top contact structure, the first semiconductor layer 16a is not oxidized and the S value becomes small, so that high-speed switching can be performed. Thus, in the display device 100a in which the first TFT 9A and the second TFT 9B each using the oxide semiconductor are provided in the subpixel P, the characteristics of the first TFT 9A and the second TFT 9B can be optimized.

### Second Embodiment

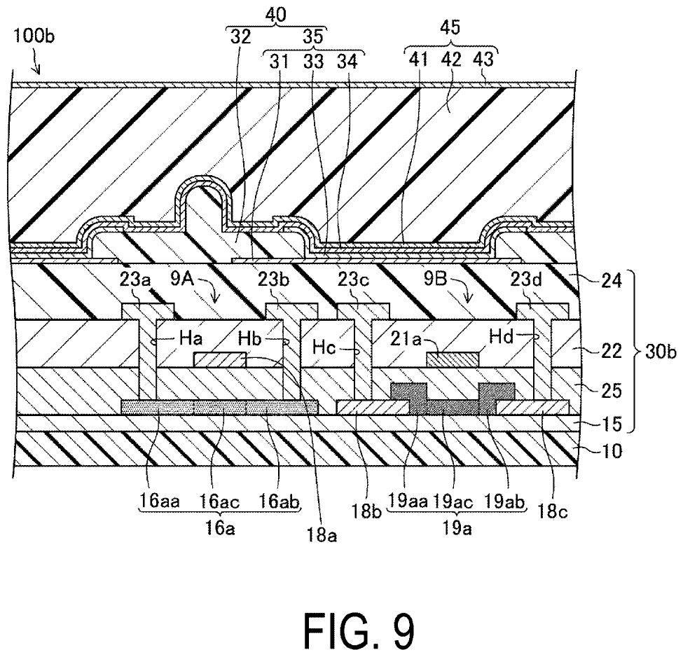

FIGS. 9 to 12 illustrate a second embodiment of the display device according to the disclosure. Here, FIG. 9 is a cross-sectional view of an organic EL display device 100b according to the present embodiment. Note that, in each of the following embodiments, the same portions as those in FIG. 1 to FIG. 8 are denoted by the same reference signs, and a detailed description of these portions is omitted.

In the first embodiment, the organic EL display device 100a including the TFT layer 30a in which the first semiconductor layer 16a of the first TFT 9A is provided closer to the resin substrate 10 than the second semiconductor layer 19a of the second TFT 9B is illustrated, while in the present embodiment, the organic EL display device 100b including a TFT layer 30b in which the first semiconductor layer 16a of the first TFT 9A and the second semiconductor layer 19a of the second TFT 9B are provided in the same layer using the same material will be illustrated.

Similar to the organic EL display device 100a in the first embodiment, the organic EL display device 100b includes the display region 50 in which the plurality of subpixels P are provided in the matrix shape, and the gate driver 60, the emission driver 70, and the source driver 80 provided in the frame region around the display region 50. Note that similar to the organic EL display device 100a in the first embodiment, the display control circuit 150 electrically connected to the gate driver 60, the emission driver 70, and the source driver 80 is provided outside the organic EL display device 100b.

As illustrated in FIG. 9, the organic EL display device 100b includes the resin substrate 10 provided as the base substrate, the TFT layer 30b provided on the resin substrate 10, the organic EL element layer 40 provided as the light-emitting element layer on the TFT layer 30b, and the sealing film 45 provided on the organic EL element layer 40.

As illustrated in FIG. 9, the TFT layer 30b includes the base coat film 15 provided on the resin substrate 10, six first TFTs 9A, one second TFT 9B, and one capacitor 9h provided on the base coat film 15 for each subpixel P, and the flattening film 24 provided on each first TFT 9A, each second TFT 9B, and each capacitor 9h.

Similar to the TFT layer 30a in the first embodiment, in the display region 50 of the TFT layer 30b, i pieces of the first scanning signal lines PS(1) to PS(i), (i+1) pieces of the second scanning signal lines NS(0) to NS(i), i pieces of the light emission control lines EM(1) to EM(i), j pieces of the data signal lines D(1) to D(j), the high-level power supply line ELVDD, the low-level power supply line ELVSS, and the initialization power supply line Vini are provided.

As illustrated in FIG. 9, the first TFT 9a includes the first semiconductor layer 16a provided on the base coat film 15, the first gate electrode 18a provided on the first semiconductor layer 16a with a common gate insulating film 25 interposed therebetween, and the first terminal electrode 23a and the second terminal electrode 23b provided separated from each other on the interlayer insulating film 22. Here, as illustrated in FIG. 9, the first TFT 9A has the top contact structure and is provided so that the S value becomes small. The common gate insulating film 25 is provided as a common inorganic insulating film that also serves as a first inorganic insulating film that electrically insulates the first semiconductor layer 16a and the first gate electrode 18a from each other and a second inorganic insulating film that electrically insulates the second semiconductor layer 19a and the second gate electrode 21a from each other.

As illustrated in FIG. 9, the first terminal electrode 23a and the second terminal electrode 23b are electrically connected to the first conductor region 16aa and the second conductor region 16ab of the first semiconductor layer 16a through a first contact hole Ha and a second contact hole Hb, respectively, formed in the layered film of the common gate insulating film 25 and the interlayer insulating film 22.

As illustrated in FIG. 9, the second TFT 9B includes the second semiconductor layer 19a provided on the base coat film 15, the first relay electrode 18b and the second relay electrode 18c provided separated from each other on the resin substrate 10 side of the second semiconductor layer 19a, the second gate electrode 21a provided on the second semiconductor layer 19a with the common gate insulating film 25 interposed therebetween, and a third terminal electrode 23c and a fourth terminal electrode 23d provided separated from each other on the interlayer insulating film 22. Here, as illustrated in FIG. 9, the second TFT 9B has a bottom contact structure, for example, in order to form the first relay electrode 18b and the second relay electrode 18c, the oxide semiconductor is oxidated due to oxygen ashing at the time of patterning the first metal film by dry etching and a trace amount of residues of a first metal film, and thus, the second TFT 9B is provided so that the S value becomes large.

As illustrated in FIG. 9, the first relay electrode 18b and the second relay electrode 18c are provided on the base coat film 15 and are provided so as to be in contact with lower faces of the third conductor region 19aa and the fourth conductor region 19ab of the second semiconductor layer 19a, respectively.

As illustrated in FIG. 9, the third terminal electrode 23c and the fourth terminal electrode 23d are electrically connected to the first relay electrode 18b and the second relay electrode 18c through a third contact hole Hc and a fourth contact hole Hd, respectively, formed in the layered film of the common gate insulating film 25 and the interlayer insulating film 22.

As illustrated in FIG. 9, in the TFT layer 30b, the base coat film 15, the first metal film serving as the first relay electrode 18b and the like, the semiconductor film serving as the first semiconductor layer 16a, the second semiconductor layer 19a, and the like, the common gate insulating film 25, the second metal film serving as the first gate electrode 18a, the second gate electrode 21a and the like, the interlayer insulating film 22, the third metal film serving as the first terminal electrode 23a and the like, and the flattening film 24 are sequentially layered on the resin substrate 10.

Similar to the TFT layer 30a in the first embodiment, in the present embodiment, the initialization TFT 9a, the threshold voltage compensation TFT 9b, the write control TFT 9c, the power supply control TFT 9e, the light emission control TFT 9f, and the anode discharge TFT 9g are provided as the first TFT 9A, and the drive TFT 9d is provided as the second TFT 9B.

Similar to the operation of the organic EL display device 100a of the first embodiment described above, in the organic EL display device 100b having the configuration described above, in each subpixel P, the organic EL element 35 emits light at luminance corresponding to a drive current to perform the image display.

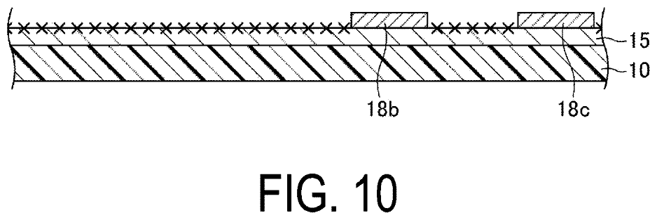

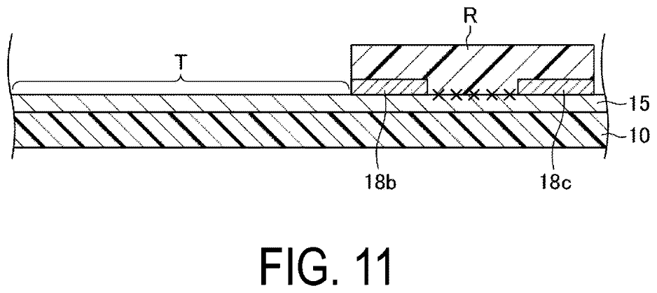

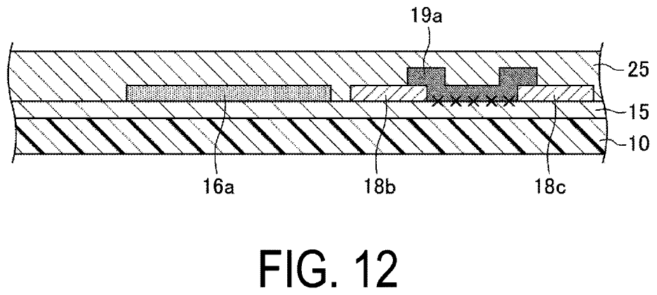

Next, a method for manufacturing the organic EL display device 100b according to the present embodiment will be described. Note that the method for manufacturing the organic EL display device 100b includes a TFT layer forming step, an organic EL element layer forming step, and a sealing film forming step. FIG. 10 is a cross-sectional view illustrating a part of a forming step of the TFT layer 30b. FIG. 11 is a cross-sectional view illustrating a part of a forming step of the TFT layer 30b subsequent to FIG. 10. FIG. 12 is a cross-sectional view illustrating a part of a forming step of the TFT layer 30b subsequent to FIG. 11.

### TFT Layer Forming Step

First, similar to the TFT layer forming step of the first embodiment, the base coat film 15 is formed.

Subsequently, after forming a first metal film by forming a molybdenum film (having a thickness of about 250 nm) or the like by, for example, sputtering on the substrate surface on which the base coat film 15 is formed, the first metal film is patterned to form the first relay electrode 18b, the second relay electrode 18c, the first scanning signal line 18g, the light emission control line 18e, and the like as illustrated in FIG. 10. At this time, on the surface of the base coat film 15 exposed from the first relay electrode 18b, the second relay electrodes 18c, and the like, as indicated by x marks in FIG. 10, oxygen is adsorbed by oxygen ashing at the time of dry etching using a chlorine-based gas or the like and oxygen adsorbed by residues of the first metal film.

Thereafter, after forming a resist pattern R on the surface of the substrate on which the first relay electrode 18b and the like are formed so as to cover the space between the first relay electrode 18b and the second relay electrode 18c, a surface treatment T such as dry etching using a fluorine-based gas or the like or wet etching using hydrofluoric acid or the like is performed on the surface of the base coat film 15 exposed from the resist pattern R as illustrated in FIG. 11 to partially remove oxygen adsorbed on the surface of the base coat film 15.

Furthermore, after forming the semiconductor film made of an oxide semiconductor by depositing InGaZnO₄ (having a thickness of about 30 nm) or the like by, for example, sputtering on the substrate surface on which the surface treatment T is performed and the resist pattern R is removed, the semiconductor film is patterned to form the first semiconductor layer 16a, the second semiconductor layer 19a, and the like.

Subsequently, a silicon oxide film (having a thickness of about 100 nm) is formed by, for example, plasma CVD, on the substrate surface on which the first semiconductor layer 16a and the like is formed, thereby forming the common gate insulating film 25 as illustrated in FIG. 12.

Thereafter, after forming a second metal film by forming a single-layer film of a molybdenum film (having a thickness of about 250 nm), a layered film in which an aluminum film (having a thickness of about 300 nm) and a titanium film (having a thickness of about 50 nm) are sequentially layered, or a layered film in which a titanium film (having a thickness of about 50 nm), an aluminum film (having a thickness of about 300 nm), and a titanium film (having a thickness of about 50 nm) are sequentially layered by, for example, sputtering on the substrate surface on which the common gate insulating film 25 is formed, the second metal film is patterned to form the first gate electrode 18a, the second gate electrode 21a, the second scanning signal line 21d, the initialization power supply line 21i, and the like.

Furthermore, on the substrate surface on which the first gate electrode 18a and the like are formed, a silicon oxide film (having a thickness of about 300 nm) and a silicon nitride film (having a thickness of about 150 nm) are sequentially formed by, for example, plasma CVD to form the interlayer insulating film 22. Note that by performing heat treatment after forming the interlayer insulating film 22, a part of the first semiconductor layer 16a and a part of the second semiconductor layer 19a are made conductive, and the first conductor region 16aa, the second conductor region 16ab, and the first channel region 16ac are formed in the first semiconductor layer 16a, and the third conductor region 19aa, the fourth conductor region 19ab, and the second channel region 19ac are formed in the second semiconductor layer 19a.

Thereafter, on the substrate surface on which the interlayer insulating film 22 is formed, the common gate insulating film 25 and the interlayer insulating film 22 are appropriately patterned to form the first contact hole Ha, the second contact hole Hb, the third contact hole Hc, and the fourth contact hole Hd.

Furthermore, after forming a third metal film by sequentially forming a titanium film (having a thickness of about 50 nm), an aluminum film (having a thickness of about 400 nm), a titanium film (having a thickness of about 50 nm) and the like by, for example, sputtering, on the substrate surface on which the first contact hole Ha and the like are formed, the third metal film is patterned to form the first terminal electrode 23a, the second terminal electrode 23b, the third terminal electrode 23c, the fourth terminal electrode 23d, the data signal line 23g, the high-level power supply line 23h, and the like.

Finally, after applying a polyimide-based photosensitive resin film (having a thickness of about 2 μm) to the substrate surface on which the first terminal electrode 23a and the like are formed, by, for example, spin coating or slit coating, pre-baking, exposing, developing, and post-baking are performed on the applied film to form the flattening film 24.

As described above, the TFT layer 30b can be formed.

Thereafter, similar to the first embodiment, the organic EL element layer forming step and the sealing film forming step are performed, whereby the organic EL display device 100b of the present embodiment can be manufactured.

As described above, according to the organic EL display device 100b of the present embodiment, the initialization TFT 9a, the threshold voltage compensation TFT 9b, the write control TFT 9c, the power supply control TFT 9e, the light emission control TFT 9f, and the anode discharge TFT 9g each provided as the first TFT 9A each have the top contact structure, and the drive TFT 9d provided as the second TFT 9B has the bottom contact structure. Here, in the drive TFT 9d having the bottom contact structure, when the first relay electrode 18b and the second relay electrode 18c are formed, oxygen is adsorbed on the surface of the base coat film 15. Thus, the second semiconductor layer 19a formed thereafter is oxidized. As a result, since the S value becomes large in the drive TFT 9d, the luminance of the organic EL element 35 of each subpixel P can be finely controlled by finely controlling the current value flowing through the organic EL element 35. On the other hand, in the initialization TFT 9a, the threshold voltage compensation TFT 9b, the write control TFT 9c, the power supply control TFT 9e, the light emission control TFT 9f, and the anode discharge TFT 9g having the top contact structure, when the first relay electrode 18b and the second relay electrode 18c are formed, oxygen is temporarily adsorbed on the surface of the base coat film 15. However, oxygen on the surface of the base coat film 15 is removed before the first semiconductor layer 16a is formed, and thus, the first semiconductor layer 16a is not oxidized and the S value becomes small, so that high-speed switching can be performed. Thus, in the display device 100b in which the first TFT 9A and the second TFT 9B each using the oxide semiconductor are provided in the subpixel P, the characteristics of the first TFT 9A and the second TFT 9B can be optimized.

### Third Embodiment

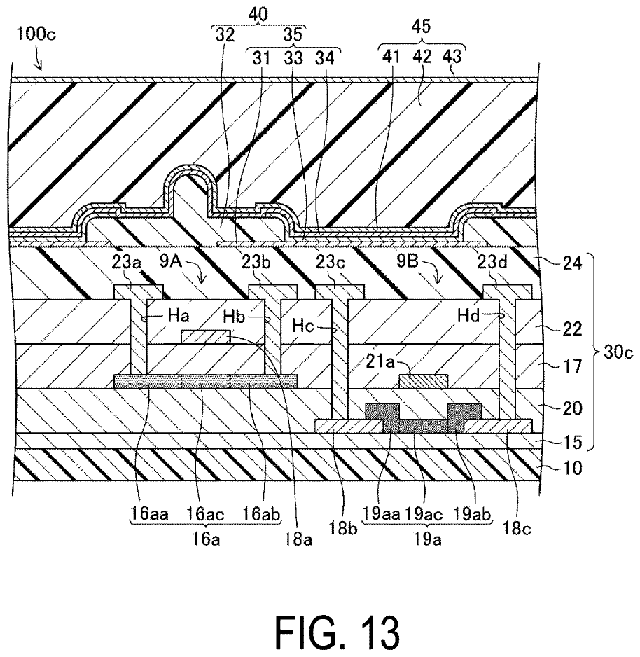

FIGS. 13 to 17 illustrates a third embodiment of the display device according to the disclosure. Here, FIG. 13 is a cross-sectional view of an organic EL display device 100c according to the present embodiment.

In the first embodiment, the organic EL display device 100a including the TFT layer 30a in which the first semiconductor layer 16a of the first TFT 9A is provided closer to the resin substrate 10 than the second semiconductor layer 19a of the second TFT 9B is illustrated, while in the present embodiment, the organic EL display device 100c including a TFT layer 30c in which the second semiconductor layer 19a of the second TFT 9B is provided closer to the resin substrate 10 than the first semiconductor layer 16a of the first TFT 9A.

Similar to the organic EL display device 100a in the first embodiment, the organic EL display device 100c includes the display region 50 in which the plurality of subpixels P are provided in the matrix shape, and the gate driver 60, the emission driver 70, and the source driver 80 provided in the frame region around the display region 50. Note that similar to the organic EL display device 100a in the first embodiment, the display control circuit 150 electrically connected to the gate driver 60, the emission driver 70, and the source driver 80 is provided outside the organic EL display device 100c.

As illustrated in FIG. 13, the organic EL display device 100c includes the resin substrate 10 provided as the base substrate, the TFT layer 30c provided on the resin substrate 10, the organic EL element layer 40 provided as the light-emitting element layer on the TFT layer 30c, and the sealing film 45 provided on the organic EL element layer 40.

As illustrated in FIG. 13, the TFT layer 30c includes the base coat film 15 provided on the resin substrate 10, six first TFTs 9A, one second TFT 9B, and one capacitor 9h provided on the base coat film 15 for each subpixel P, and the flattening film 24 provided on each first TFT 9A, each second TFT 9B, and each capacitor 9h.

Similar to the TFT layer 30a in the first embodiment, in the display region 50 of the TFT layer 30c, i pieces of the first scanning signal lines PS(1) to PS(i), (i+1) pieces of the second scanning signal lines NS(0) to NS(i), i pieces of the light emission control lines EM(1) to EM(i), j pieces of the data signal lines D(1) to D(j), the high-level power supply line ELVDD, the low-level power supply line ELVSS, and the initialization power supply line Vini are provided.

As illustrated in FIG. 13, the first TFT 9A includes the first semiconductor layer 16a provided on the second gate insulating film 20, a first gate electrode 18a provided on the first semiconductor layer 16a with the first gate insulating film 17 interposed therebetween, and a first terminal electrode 23a and a second terminal electrode 23b provided separated from each other on the interlayer insulating film 22. Here, as illustrated in FIG. 13, the first TFT 9A has the top contact structure and is provided so that the S value becomes small.

As illustrated in FIG. 13, the first terminal electrode 23a and the second terminal electrode 23b are electrically connected to the first conductor region 16aa and the second conductor region 16ab of the first semiconductor layer 16a through a first contact hole Ha and a second contact hole Hb, respectively, formed in the layered film of the first gate insulating film 17 and the interlayer insulating film 22.

As illustrated in FIG. 13, the second TFT 9B includes the second semiconductor layer 19a provided on the base coat film 15, the first relay electrode 18b and the second relay electrode 18c provided separated from each other on the resin substrate 10 side of the second semiconductor layer 19a, the second gate electrode 21a provided on the second semiconductor layer 19a with the second gate insulating film 20 interposed therebetween, and a third terminal electrode 23c and a fourth terminal electrode 23d provided separated from each other on the interlayer insulating film 22. Here, as illustrated in FIG. 13, the second TFT 9B has a bottom contact structure, for example, in order to form the first relay electrode 18b and the second relay electrode 18c, the oxide semiconductor is oxidated due to oxygen ashing at the time of patterning the first metal film by dry etching and a trace amount of residues of a first metal film, and thus, the second TFT 9B is provided so that the S value becomes large.

As illustrated in FIG. 13, the first relay electrode 18b and the second relay electrode 18c are provided on the base coat film 15 and are provided so as to be in contact with lower faces of the third conductor region 19aa and the fourth conductor region 19ab of the second semiconductor layer 19a, respectively.

As illustrated in FIG. 13, the third terminal electrode 23c and the fourth terminal electrode 23d are electrically connected to the first relay electrode 18b and the second relay electrode 18c through a third contact hole Hc and a fourth contact hole Hd, respectively, formed in the layered film of the second gate insulating film 20, the first gate insulating film 17, and the interlayer insulating film 22.

Note that as illustrated in FIG. 13, in the TFT layer 30c, the base coat film 15, the first metal film serving as the first relay electrode 18b and the like, the second semiconductor film serving as the second semiconductor layer 19a and the like, the second gate insulating film 20, the second metal film serving as the second gate electrode 21a and the like, the first semiconductor film serving as the first semiconductor layer 16a and the like, the first gate insulating film 17, the third metal film serving as the first gate electrode 18a and the like, the interlayer insulating film 22, the fourth metal film serving as the first terminal electrode 23a, and the flattening film 24 are sequentially layered on the resin substrate 10.

Similar to the TFT layer 30a in the first embodiment, in the present embodiment, the initialization TFT 9a, the threshold voltage compensation TFT 9b, the write control TFT 9c, the power supply control TFT 9e, the light emission control TFT 9f, and the anode discharge TFT 9g are provided as the first TFT 9A, and the drive TFT 9d is provided as the second TFT 9B.

Similar to the operation of the organic EL display device 100a of the first embodiment described above, in the organic EL display device 100c having the configuration described above, in each subpixel P, the organic EL element 35 emits light at luminance corresponding to a drive current to perform the image display.

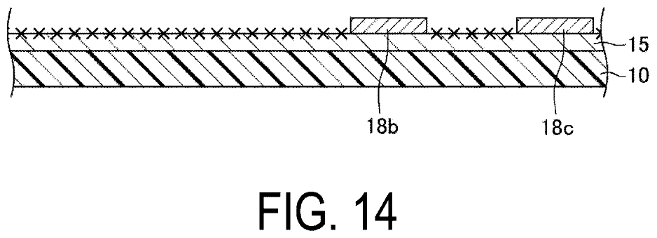

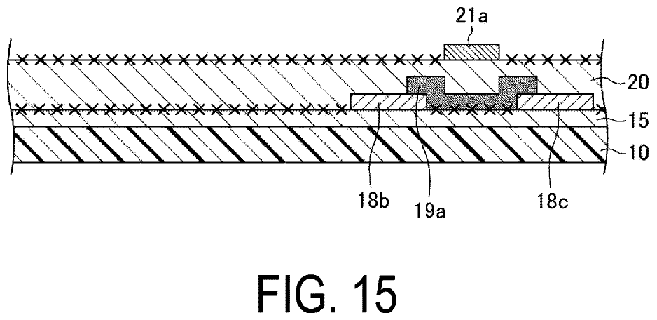

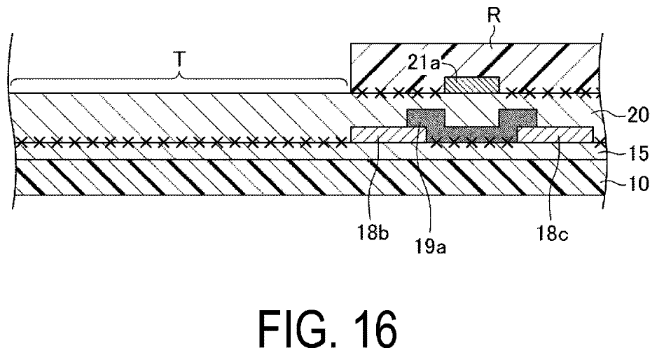

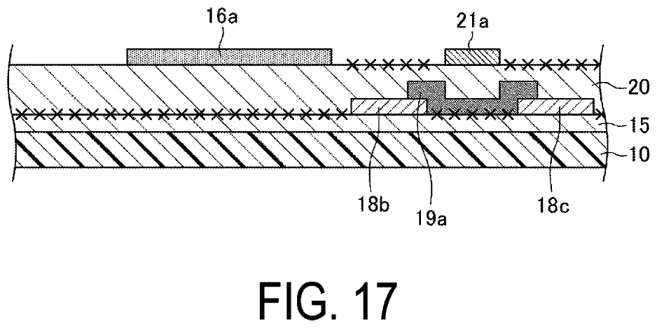

Next, a method for manufacturing the organic EL display device 100c according to the present embodiment will be described. Note that the method for manufacturing the organic EL display device 100c includes a TFT layer forming step, an organic EL element layer forming step, and a sealing film forming step. FIG. 14 is a cross-sectional view illustrating a part of a forming step of the TFT layer 30c. FIG. 15 is a cross-sectional view illustrating a part of a forming step of the TFT layer 30c subsequent to FIG. 14. FIG. 16 is a cross-sectional view illustrating a part of a forming step of the TFT layer 30c subsequent to FIG. 15. FIG. 17 is a cross-sectional view illustrating a part of a forming step of the TFT layer 30c subsequent to FIG. 16.

TFT Layer Forming Step First, similar to the TFT layer forming step of the first embodiment, the base coat film 15 is formed.

Subsequently, after forming a first metal film by forming a molybdenum film (having a thickness of about 250 nm) or the like by, for example, sputtering on the substrate surface on which the base coat film 15 is formed, the first metal film is patterned to form the first relay electrode 18b, the second relay electrode 18c, the first scanning signal line 18g, the light emission control line 18e, and the like as illustrated in FIG. 14. At this time, on the surface of the base coat film 15 exposed from the first relay electrode 18b and the second relay electrodes 18c, as indicated by x marks in FIG. 14, oxygen is adsorbed by oxygen ashing at the time of dry etching using a chlorine-based gas or the like and oxygen adsorbed by residues of the first metal film.

Thereafter, after forming the second semiconductor film made of an oxide semiconductor by depositing InGaZnO₄ (having a thickness of about 30 nm) or the like by, for example, sputtering on the substrate surface on which the first relay electrode 18b and the like are formed, the second semiconductor film is patterned to form the second semiconductor layer 19a and the like. At this time, the second semiconductor layer 19a is oxidized by diffusion of oxygen on the surface of the base coat film 15 (see FIG. 15).

Furthermore, a silicon oxide film (having a thickness of approximately 100 nm) is formed by, for example, plasma CVD on the substrate surface on which the second semiconductor layer 19a and the like are formed, thereby forming the second gate insulating film 20.

Subsequently, after forming the second metal film, by forming a molybdenum film (having a thickness of about 250 nm) or the like by, for example, sputtering on the substrate surface on which the second gate insulating film 20 is formed, the second metal film is patterned to form the second gate electrode 21a, the second scanning signal line 21d, the initialization power supply line 21i, and the like as illustrated in FIG. 15. At this time, on the surface of the second gate insulating film 20 exposed from the second gate electrodes 21a and the like, as indicated by x marks in FIG. 15, oxygen is adsorbed by oxygen ashing at the time of dry etching using a chlorine-based gas or the like and oxygen adsorbed by residues of the second metal film.

Thereafter, after forming the resist pattern R so as to cover the second gate electrode 21a, dry etching using a fluorine-based gas or the like or wet etching using hydrofluoric acid or the like is performed on the surface of the second gate insulating film 20 exposed from the resist pattern R as illustrated in FIG. 16 to partially remove oxygen adsorbed on the surface of the second gate insulating film 20.

Furthermore, after forming the first semiconductor film made of an oxide semiconductor by depositing InGaZnO₄ (having a thickness of about 30 nm) or the like by, for example, sputtering on the substrate surface on which the surface treatment Tis performed and the resist pattern R is removed, the first semiconductor film is patterned to form the first semiconductor layer 16a and the like as illustrated in FIG. 17.

Subsequently, a silicon oxide film (having a thickness of approximately 100 nm) is formed by, for example, plasma CVD, on the substrate surface where the first semiconductor layer 16a and the like is formed, thereby forming the first gate insulating film 17.

Thereafter, after forming a third metal film by forming a single-layer film of a molybdenum film (having a thickness of about 250 nm), a layered film in which an aluminum film (having a thickness of about 300 nm) and a titanium film (having a thickness of about 50 nm) are sequentially layered, or a layered film in which a titanium film (having a thickness of about 50 nm), an aluminum film (having a thickness of about 300 nm), and a titanium film (having a thickness of about 50 nm) are sequentially layered by, for example, sputtering on the substrate surface on which the first gate insulating film 17 is formed, the third metal film is patterned to form the first gate electrode 18a and the like.

Furthermore, on the substrate surface on which the first gate electrode 18a and the like are formed, a silicon oxide film (having a thickness of about 300 nm) and a silicon nitride film (having a thickness of about 150 nm) are sequentially formed by, for example, plasma CVD to form the interlayer insulating film 22. Note that by performing heat treatment after forming the interlayer insulating film 22, a part of the first semiconductor layer 16a and a part of the second semiconductor layer 19a are made conductive, and the first conductor region 16aa, the second conductor region 16ab, and the first channel region 16ac are formed in the first semiconductor layer 16a, and the third conductor region 19aa, the fourth conductor region 19ab, and the second channel region 19ac are formed in the second semiconductor layer 19a.

Thereafter, on the substrate surface on which the interlayer insulating film 22 is formed, the second gate insulating film 20, the first gate insulating film 17, and the interlayer insulating film 22 are appropriately patterned to form the first contact hole Ha, the second contact hole Hb, the third contact hole Hc, and the fourth contact hole Hd.

Furthermore, after forming a fourth metal film by sequentially forming a titanium film (having a thickness of about 50 nm), an aluminum film (having a thickness of about 400 nm), a titanium film (having a thickness of about 50 nm) and the like by, for example, sputtering, on the substrate surface on which the first contact hole Ha and the like are formed, the fourth metal film is patterned to form the first terminal electrode 23a, the second terminal electrode 23b, the third terminal electrode 23c, the fourth terminal electrode 23d, the data signal line 23g, the high-level power supply line 23h, and the like.

Finally, after applying a polyimide-based photosensitive resin film (having a thickness of about 2 μm) to the substrate surface on which the first terminal electrode 23a and the like are formed, by, for example, spin coating or slit coating, pre-baking, exposing, developing, and post-baking are performed on the applied film to form the flattening film 24.

As described above, the TFT layer 30c can be formed.

Thereafter, similar to the first embodiment, the organic EL element layer forming step and the sealing film forming step are performed, whereby the organic EL display device 100c of the present embodiment can be manufactured.

As described above, according to the organic EL display device 100c of the present embodiment, the initialization TFT 9a, the threshold voltage compensation TFT 9b, the write control TFT 9c, the power supply control TFT 9e, the light emission control TFT 9f, and the anode discharge TFT 9g each provided as the first TFT 9A each have the top contact structure, and the drive TFT 9d provided as the second TFT 9B has the bottom contact structure. Here, in the drive TFT 9d having the bottom contact structure, when the first relay electrode 18b and the second relay electrode 18c are formed, oxygen is adsorbed on the surface of the base coat film 15. Thus, the second semiconductor layer 19a formed thereafter is oxidized. As a result, since the S value becomes large in the drive TFT 9d, the luminance of the organic EL element 35 of each subpixel P can be finely controlled by finely controlling the current value flowing through the organic EL element 35. On the other hand, in the initialization TFT 9a, the threshold voltage compensation TFT 9b, the write control TFT 9c, the power supply control TFT 9e, the light emission control TFT 9f, and the anode discharge TFT 9g each having the top contact structure, when the second gate electrodes 21a is formed, oxygen is temporarily adsorbed on the surface of the second gate insulating film 20. However, oxygen on the surface of the second gate insulating film 20 is removed before the first semiconductor layer 16a is formed, and thus, the first semiconductor layer 16a is not oxidized and the S value becomes small, so that high-speed switching can be performed. Thus, in the display device 100c in which the first TFT 9A and the second TFT 9B each using the oxide semiconductor are provided in the subpixel P, the characteristics of the first TFT 9A and the second TFT 9B can be optimized.

### OTHER EMBODIMENTS

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

In each of the embodiments described above, the organic EL display device has been exemplified as the display device. The disclosure can also be applied to a display device including a plurality of light-emitting elements to be driven by a current, for example, to a display device including quantum dot light-emitting diodes (QLEDs), each of which is a light-emitting element using a quantum dot-containing layer.

### INDUSTRIAL APPLICABILITY

As described above, the disclosure is useful for a flexible display device.

1. A display device, comprising:
a base substrate; and
a thin film transistor layer provided on the base substrate,
wherein, in the thin film transistor layer,
a first thin film transistor including a first semiconductor layer made of an oxide semiconductor and a second thin film transistor including a second semiconductor layer made of an oxide semiconductor are provided for each of subpixels constituting a display region,
the first thin film transistor includes
the first semiconductor layer in which a first conductor region and a second conductor region are defined to be separated from each other and a first channel region is defined between the first conductor region and the second conductor region,
a first gate electrode provided on the first semiconductor layer via a first inorganic insulating film to overlap the first channel region, and
a first terminal electrode and a second terminal electrode provided to be separated from each other on a side opposite to the base substrate than the first gate electrode and electrically connected to the first conductor region and the second conductor region, respectively, and
the second thin film transistor includes
the second semiconductor layer in which a third conductor region and a fourth conductor region are defined to be separated from each other and a second channel region is defined between the third conductor region and the fourth conductor region,
a first relay electrode and a second relay electrode provided on a base substrate side of the second semiconductor layer and arranged in contact with the third conductor region and the fourth conductor region, respectively,
a second gate electrode provided on the second semiconductor layer to overlap the second channel region via a second inorganic insulating film, and
a third terminal electrode and a fourth terminal electrode provided to be separated from each other on a side opposite to the base substrate with respect to the second gate electrode and electrically connected to the first relay electrode and the second relay electrode, respectively.

2. The display device according to claim 1,
wherein as the second thin film transistor, a drive thin film transistor is provided.

3. The display device according to claim 2,
wherein as the first thin film transistor, an initialization thin film transistor, a threshold voltage compensation thin film transistor, a write control thin film transistor, a power supply control thin film transistor, a light emission control thin film transistor, and an anode discharge thin film transistor are provided.

4. The display device according to claim 1,
wherein the second inorganic insulating film is provided to cover the first gate electrode,
the first relay electrode and the second relay electrode are provided on the first inorganic insulating film, and
a third inorganic insulating film is provided to cover the second gate electrode.

5. The display device according to claim 4,
wherein the first terminal electrode and the second terminal electrode are electrically connected to the first conductor region and the second conductor region through a first contact hole and a second contact hole, respectively, formed in a layered film of the first inorganic insulating film, the second inorganic insulating film, and the third inorganic insulating film, and
the third terminal electrode and the fourth terminal electrode are electrically connected to the first relay electrode and the second relay electrode through a third contact hole and a fourth contact hole, respectively, formed in a layered film of the second inorganic insulating film and the third inorganic insulating film.

6. The display device according to claim 1,
wherein the thin film transistor layer includes a fourth inorganic insulating film provided on the base substrate,
the first semiconductor layer, the first relay electrode, and the second relay electrode are provided on the fourth inorganic insulating film,
the first inorganic insulating film and the second inorganic insulating film are provided as a common inorganic insulating film, and
a third inorganic insulating film is provided to cover the first gate electrode and the second gate electrode.

7. The display device according to claim 6,
wherein the first terminal electrode and the second terminal electrode are electrically connected to the first conductor region and the second conductor region through a first contact hole and a second contact hole, respectively, formed in a layered film of the common inorganic insulating film and the third inorganic insulating film, and
the third terminal electrode and the fourth terminal electrode are electrically connected to the first relay electrode and the second relay electrode through a third contact hole and a fourth contact hole, respectively, formed in the layered film of the common inorganic insulating film and the third inorganic insulating film.

8. The display device according to claim 1,
wherein the thin film transistor layer includes a fourth inorganic insulating film provided on the base substrate,
the first relay electrode and the second relay electrode are provided on the fourth inorganic insulating film,
the first semiconductor layer is provided on the second inorganic insulating film,
the first inorganic insulating film is provided to cover the second gate electrode, and
a third inorganic insulating film is provided to cover the first gate electrode.

9. The display device according to claim 8,
wherein the first terminal electrode and the second terminal electrode are electrically connected to the first conductor region and the second conductor region through a first contact hole and a second contact hole, respectively, formed in a layered film of the first inorganic insulating film and the third inorganic insulating film, and
the third terminal electrode and the fourth terminal electrode are electrically connected to the first relay electrode and the second relay electrode through a third contact hole and a fourth contact hole, respectively, formed in the layered film of the second inorganic insulating film, the first inorganic insulating film, and the third inorganic insulating film.

10. The display device according to claim 1, further comprising:
a light-emitting element layer provided on the thin film transistor layer and constituting a plurality of light-emitting elements arrayed in correspondence with a plurality of subpixels included in the display region; and
a sealing film provided on the light-emitting element layer.

11. The display device according to claim 10,
wherein each of the plurality of light-emitting elements is an organic electroluminescence element.
